(19) United States
(12) Patent Application Publication
(10) Pub. No.: US 2015/0053457 A1
(43) Pub. Date: Feb. 26, 2015

(54) PRINTED CIRCUIT BOARD AND METHOD OF MANUFACTURING THE SAME

(71) Applicant: SAMSUNG ELECTRO-MECHANICS., LTD., SUWON-SI (KR)

(72) Inventors: SUNG HAN KIM, SUWON-SI (KR); JIN HO HONG, SUWON-SI (KR); YONG II KWON, SUWON-SI (KR); SA YONG LEE, SUWON-SI (KR); EUN SIL KIM, SUWON-SI (KR); SANG HYUN SHIN, SUWON-SI (KR); KEUN YONG LEE, SUWON-SI (KR)

(73) Assignee: SAMSUNG ELECTRO-MECHANICS., LTD., SUWON-SI (KR)

(21) Appl. No.: 14/196,324

(22) Filed: Mar. 4, 2014

(30) Foreign Application Priority Data
Aug. 26, 2013 (KR) 10-2013-0101110

(51) Int. Cl. H05K 3/44; H05K 1/02

(52) U.S. Cl. CPC H05K 3/44; H05K 1/0274; H05K 1/0298; H05K 2203/0502
USPC 174/251; 430/315

(57) ABSTRACT

Disclosed herein are a printed circuit board and a method of manufacturing the same. According to the preferred embodiment of the present invention, the printed circuit board includes: a glass substrate through which light is not transmitted; a positive photosensitive insulating layer formed on the glass substrate; and a circuit pattern formed on the glass substrate and buried in the positive photosensitive insulating layer.

### CROSS REFERENCE TO RELATED APPLICATION

This application claims the benefit of Korean Patent Application No. 10-2013-0101110, filed on Aug. 26, 2013, entitled “Printed Circuit Board And Method Of Manufacturing The Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

Recently, a demand for multifunctional and high-speed electronic products has rapidly increased. To cope with the trend, a semiconductor chip and a printed circuit board on which the semiconductor chip is mounted have been developed at a very rapid speed. The printed circuit board needs to be small, light, thin, and short, and requires a fine circuit, excellent electrical characteristics, high reliability, high-speed signal transfer, and the like.

According to the prior art, when a circuit pattern is formed on the printed circuit board, an order of forming the circuit pattern and then an insulating layer has progressed. The circuit pattern may be formed by forming a plating layer on the insulating layer and then performing patterning by etching the plating layer. Alternatively, the circuit pattern may be formed in an order of forming a seed layer on the insulating layer, forming a plating resist on which an opening is patterned, performing plating, removing the plating resist, and etching the seed layer. US Patent Laid-Open Publication No. 2006-0070769 discloses the method of patterning a circuit. In this case, when the plating layer or the seed layer is etched by wet etching using an etchant, an under cut may occur in the circuit pattern by an isotropic etch characteristic. In particular, a problem of the separation of the circuit pattern due to the under cut at the time of forming the fine pattern may occur.

### SUMMARY OF THE INVENTION

The present invention has been made in an effort to provide a printed circuit board capable of preventing an under cut of a circuit pattern and a method of manufacturing the same.

Further, the present invention has been made in an effort to provide a printed circuit board having large rigidity and a method of manufacturing the same.

In addition, the present invention has been made in an effort to provide a printed circuit board having reduced warpage and a method of manufacturing the same.

Moreover, the present invention has been made in an effort to provide a printed circuit board capable of facilitating implementation of a fine pattern and a method of manufacturing the same.

According to a preferred embodiment of the present invention, there is provided a printed circuit board, including: a glass substrate through which light is not transmitted; a positive photosensitive insulating layer formed on the glass substrate; and a circuit pattern formed on the glass substrate and buried in the positive photosensitive insulating layer.

The printed circuit board may further include: a through via penetrating through the glass substrate and connected to the circuit pattern.

The printed circuit board may further include: an adhesive layer formed between the glass substrate and the positive photosensitive insulating layer.

The glass substrate may be opaque.

The glass substrate may have flexibility.

The positive photosensitive insulating layer may be formed on both surfaces of the glass substrate.

According to another preferred embodiment of the present invention, there is provided a method of manufacturing a printed circuit board, including: providing a glass substrate through which light is not transmitted; forming a positive photosensitive insulating layer on the glass substrate; forming an opening on the positive photosensitive insulating layer; and forming a circuit pattern by filling the opening with a conductive material.

In the providing of the glass substrate, the glass substrate may be opaque.

The glass substrate may be formed of a glass plate which has flexibility.

The forming of the opening on the positive photosensitive insulating layer may include: exposing a region formed with the opening in the positive photosensitive insulating layer; and forming the opening by removing the exposed region by a develop process.

The exposing may include: forming a patterned mask on the positive photosensitive insulating layer to expose a region formed with the opening; exposing a region exposed by the mask in the positive photosensitive insulating layer; and removing the mask.

In the exposing, the region formed with the opening in the positive photosensitive insulating layer may be exposed by a laser direct imaging (LDI) method.

In the forming of the circuit pattern, the opening may be filled with a conductive paste by a screen printing method.

In the forming of the circuit pattern, the opening may be filled with conductive ink by an inkjet method.

The forming of the circuit pattern may include: forming a seed layer on the positive photosensitive insulating layer and the opening; forming a plating layer on the seed layer that the opening is filled by plating; and forming the circuit pattern by polishing the plating layer so as to expose one surface of the positive photosensitive insulating layer.

The method of manufacturing a printed circuit board may further include: after the forming of the opening, forming a through via hole which penetrates through the glass substrate.

In the forming of the through via hole, the through via hole may be formed by a CNC drill or a laser drill.

In the forming of the circuit pattern, a through via may be formed by filling the through via hole with the conductive material.

The method of manufacturing a printed circuit board may further include: prior to the forming of the positive photosensitive insulating layer, forming an adhesive layer on the glass substrate.

In the forming of the positive photosensitive insulating layer, the positive photosensitive insulating layer may be formed on both surfaces of the glass substrate.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a printed circuit board according to a preferred embodiment of the present invention; and

FIGS. 2 to 14 are exemplified diagrams illustrating a method of manufacturing a printed circuit board according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

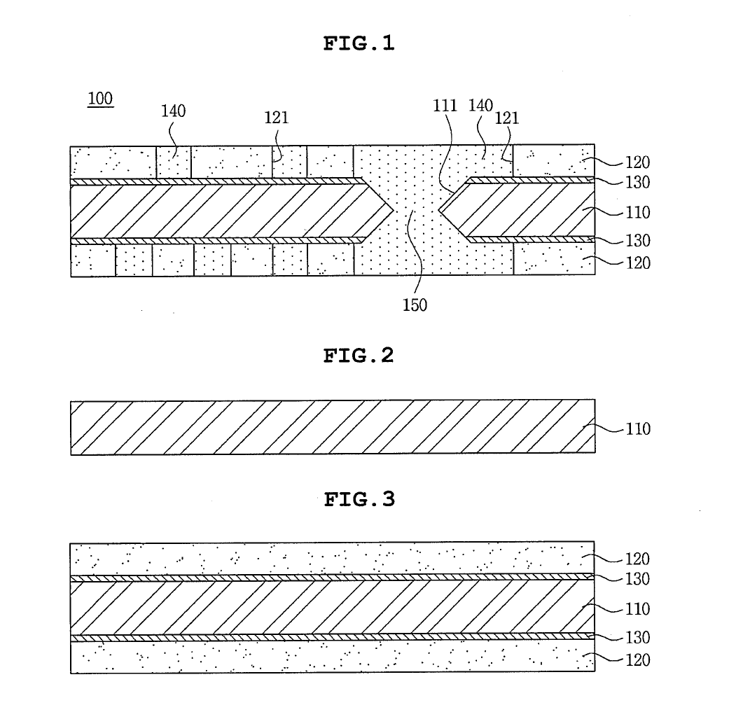

FIG. 1 is an exemplified diagram illustrating a printed circuit board according to a preferred embodiment of the present invention.

Referring to FIG. 1, a printed circuit board 100 may include a glass substrate 110, a positive photosensitive insulating layer 120, circuit patterns 140, and a through via 150.

The glass substrate 110 may be a glass plate through which light is not transmitted. When the positive photosensitive insulating layer 120 is subjected to an exposure process, the glass substrate 110 may have transparency enough to prevent light from passing through the glass substrate 110. For example, the glass substrate 110 may be an opaque glass plate. Further, the glass substrate 110 may be formed of a glass plate having flexibility. When the positive photosensitive insulating layer 120 is formed on the glass substrate 110, an existing method and a roll to roll method may be applied thanks to the glass substrate 110 having flexibility. The glass substrate 110 may perform a role of insulating between the circuit patterns 140.

The positive photosensitive insulating layer 120 may be formed on the glass substrate 110. FIG. 1 illustrates that the positive photosensitive insulating layer 120 is formed on both surfaces of the glass substrate 110, but the preferred embodiment of the present invention is not limited thereto. The positive photosensitive insulating layer 120 may be formed only on one surface of the glass substrate 110 according to a selection of a person having ordinary skill in the art to which the present invention pertains.

The positive photosensitive insulating layer 120 may perform a role of insulating between the circuit patterns 140 and a resist role. In the positive photosensitive insulating layer 120, a coupling of a photopolymer of a portion to which light is irradiated is broken during the exposure process. Next, when a develop process is performed, the positive photosensitive insulating layer 120 is patterned by removing the portion at which the coupling of the photopolymer is broken. The positive photosensitive insulating layer 120 is made of a monomolecular polymer and thus may be finely patterned.

The positive photosensitive insulating layer 120 may be patterned with an opening 121 by the foregoing exposure and develop processes. The opening 121 is formed in a region in which the circuit pattern 140 is formed and may be formed to expose the glass substrate 110.

The circuit pattern 140 may be formed in the opening 121 of the positive photosensitive insulating layer 120. That is, the circuit pattern 140 is formed on the glass substrate 110 and may be formed to be buried in the positive photosensitive insulating layer 120. The circuit pattern 140 may be made of a conductive material. For example, the circuit pattern 140 may be made of copper (Cu). However, a material of the circuit pattern 140 is not limited to copper. Any conductive material which is used in a circuit board field may be applied to the circuit pattern 140 without being limited. The circuit pattern 140 may be formed by any one of a screen print method, an inkjet method, and a plating method. When the circuit pattern 140 is formed by the plating method, an electroless plating method and an electroplating method may be applied.

The through via 150 may be formed to penetrate through the glass substrate 110. Further, the through via 150 may electrically connect between the circuit patterns 140 which are formed on both surfaces of the glass substrate 110. The through via 150 may be made of the conductive material. The through via 150 may be made of the same material as the circuit pattern 140. However, the through via 150 is not necessarily made of the same material as the circuit pattern 140, but any conductive material which is used in the circuit board field may be applied without being limited.

According to the preferred embodiment of the present invention, the printed circuit board 100 may further include an adhesive layer 130. The adhesive layer 130 may be formed on the glass substrate 110. The adhesive layer 130 may be formed to improve an adhesion between the glass substrate 110 and the positive photosensitive insulating layer 120. As a material of the adhesive layer 130, any adhesive material which is used in the circuit board field may be applied without being limited. In the present invention, the adhesive layer 130 is not an essential component and may be applied or may not be applied according to the selection of a person having ordinary skill in the art to which the present invention pertains.

The printed circuit board according to the preferred embodiment of the present invention has large rigidity due to the glass substrate and has the reduced deformation degree due to a change in temperature and humidity. Therefore, the warpage of the printed circuit board is reduced. Further, the glass substrate having flexibility has low brittleness and therefore does not easily break from an external impact, and may be applied to a printed circuit board having a curved surface. Further, the printed circuit board may be easily formed with fine circuit patterns by a smooth glass substrate and the positive photosensitive insulating layer which may be finely patterned.

FIGS. 2 to 14 are exemplified diagrams illustrating a method of manufacturing a printed circuit board according to the preferred embodiment of the present invention.

Referring to FIG. 2, the glass substrate 110 is provided.

The glass substrate 110 may be a glass plate through which light is not transmitted. When the positive photosensitive insulating layer 120 is subjected to the exposure process, the glass substrate 110 may have transparency enough to prevent light from passing through the glass substrate 110. For example, the glass substrate 110 may be the opaque glass plate. Further, the glass substrate 110 may be formed of the glass plate having flexibility. The glass substrate 110 may perform a role of insulating between circuit patterns (not illustrated) to be formed later which are made of an insulating material.

Referring to FIG. 3, the positive photosensitive insulating layer 120 is fomed on the glass substrate 110.

The positive photosensitive insulating layer 120 may perform a role of insulating between the circuit patterns 140 and a resist role. The positive photosensitive insulating layer 120 is made of a monomolecular polymer and thus may be finely patterned. FIG. 3 illustrates that the positive photosensitive insulating layer 120 is formed on both surfaces of the glass substrate 110, but the preferred embodiment of the present invention is not limited thereto. The positive photosensitive insulating layer 120 may be formed only on one surface of the glass substrate 110 according to a selection of a person having ordinary skill in the art to which the present invention pertains.

For example, the positive photosensitive insulating layer 120 may be formed on the glass substrate 110 by a roll to roll process. Here, the positive photosensitive insulating layer 120 may be formed of a film of a positive photosensitive material. According to the preferred embodiment of the present invention, the glass substrate 110 has flexibility and therefore may be applied with the roll to roll process. The flatness of the positive photosensitive insulating layer 120 formed on the glass substrate 110 may be improved by using the roll to roll process.

However, the method of forming the positive photosensitive insulating layer 120 on the glass substrate 110 is not limited to the roll to roll process. The positive photosensitive insulating layer 120 may be formed by a method of coating ink, paste, or varnish of the positive photosensitive material.

According to the preferred embodiment of the present invention, the adhesive layer 130 may be further formed, prior to forming the positive photosensitive insulating layer 120 on the glass substrate 110. The adhesive layer 130 may be formed to improve the adhesion between the glass substrate 110 and the positive photosensitive insulating layer 120. As the material of the adhesive layer 130 which is a non-conductive material, any material used to improve the adhesion in the circuit board field may be applied.

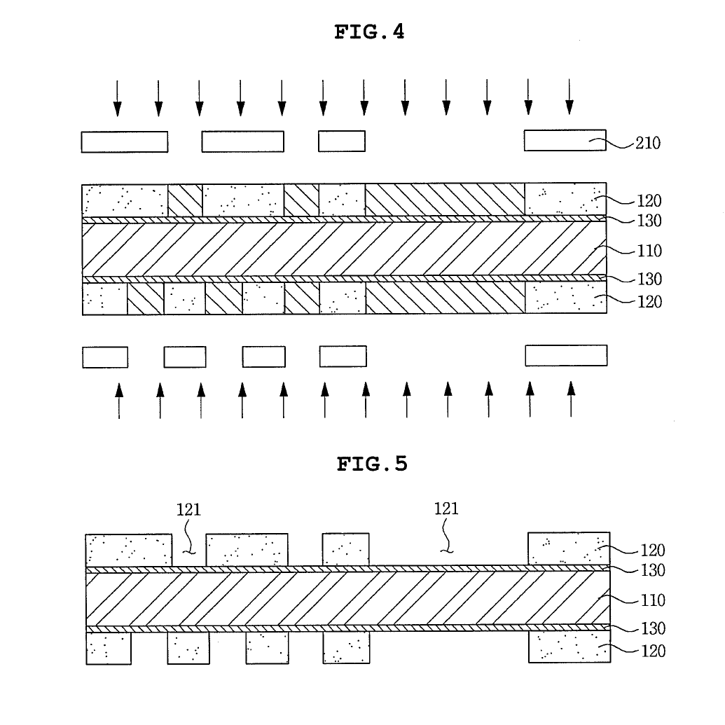

Referring to FIG. 4, the positive photosensitive insulating layer 120 is subjected to exposure.

First, a mask 210 may be formed on the positive photosensitive insulating layer 120. The mask 210 may be patterned to expose the region in which the opening (not illustrated) of the positive photosensitive insulating layer 120 is formed. Here, the opening (not illustrated) is a region in which the circuit pattern (not illustrated) is formed later. The positive photosensitive insulating layer 120 is formed with a patterned mask 210 and then is irradiated with light to perform the exposure. The light irradiated to the positive photosensitive insulating layer 120 may be an ultraviolet or laser light source. When the exposure is performed, the coupling of the photopolymer of a portion irradiated with light is broken and cured in the region irradiated with light in the positive photosensitive insulating layer 120.

FIG. 4 illustrates that the method of performing exposure on the positive photosensitive insulating layer 120 uses the mask 210, but the exposure method is not limited thereto. Although not to illustrated, only a desired region of the positive photosensitive insulating layer 120 may be exposed without using the mask 210 by using a laser direct imaging (LDI) method.

Referring to FIG. 5, the positive photosensitive insulating layer 120 is formed with the opening 121.

The exposed positive photosensitive insulating layer 120 may be developed. The positive photosensitive insulating layer 120 is exposed and thus the cured region may be removed by a developer. By the exposure and develop processes, in the positive photosensitive insulating layer 120, the region in which the circuit pattern (not illustrated) is formed may be formed with the opening 121. The opening 121 may expose the glass substrate 110.

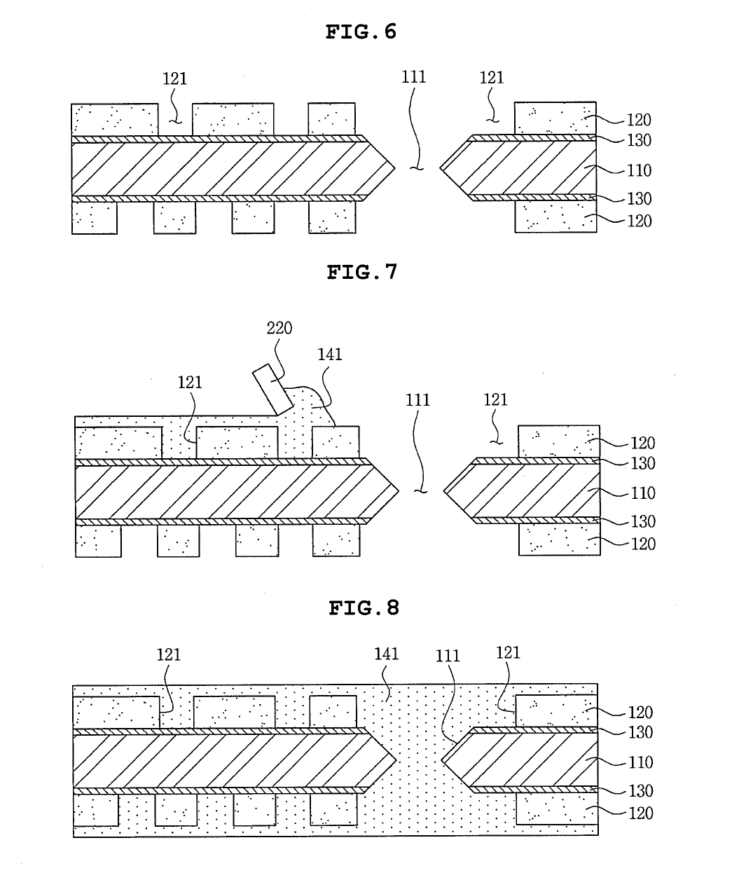

Referring to FIG. 6, the through via hole 111 may be formed.

The through via hole 111 is formed with the through via 150 through which the circuit patterns (not illustrated) formed later on both surfaces of the glass substrate 110 are electrically connected. Therefore, the through via hole 111 may be formed to penetrate through the glass substrate 110. The through via hole 111 may be formed by a CNC drill or a laser drill.

FIGS. 7 to 9 are exemplified diagrams illustrating a method of forming a circuit pattern according to the preferred embodiment of the present invention.

Referring to FIG. 7, a conductive paste 141 may be applied by the screen print method.

Referring to FIG. 8, according to the preferred embodiment of the present invention, the opening 121 of the positive photosensitive insulating layer 120 may be filled by applying the conductive paste 141 using a squeeze 220. Further, the conductive paste 141 may also be filled in the through via hole 111 to form the through via 150. The conductive paste 141 applied by the screen print method may also be applied on the opening 121 and an upper surface of the positive photosensitive insulating layer 120.

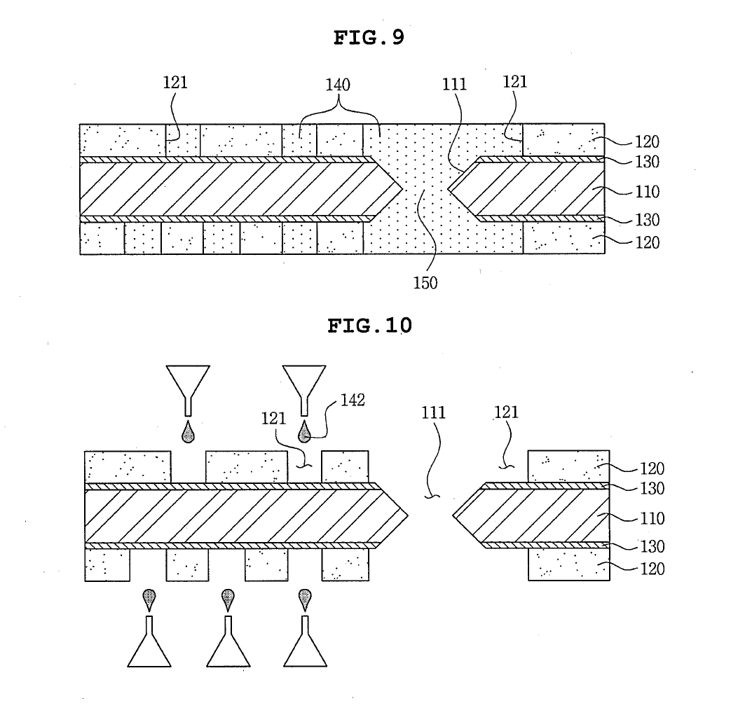

Referring to FIG. 9, the circuit pattern 140 may be formed.

When the conductive paste 141 is applied up to the upper surface of the positive photosensitive insulating layer 120, polishing may be performed. The conductive paste 141 may be removed till the upper surface of the positive photosensitive insulation layer 120 is exposed by the polishing. The circuit pattern 140 buried in the positive photosensitive insulating layer 120 may be formed by the polishing. Further, the flatness of the positive photosensitive insulating layer 120 and the circuit pattern 140 may be improved by the polishing.

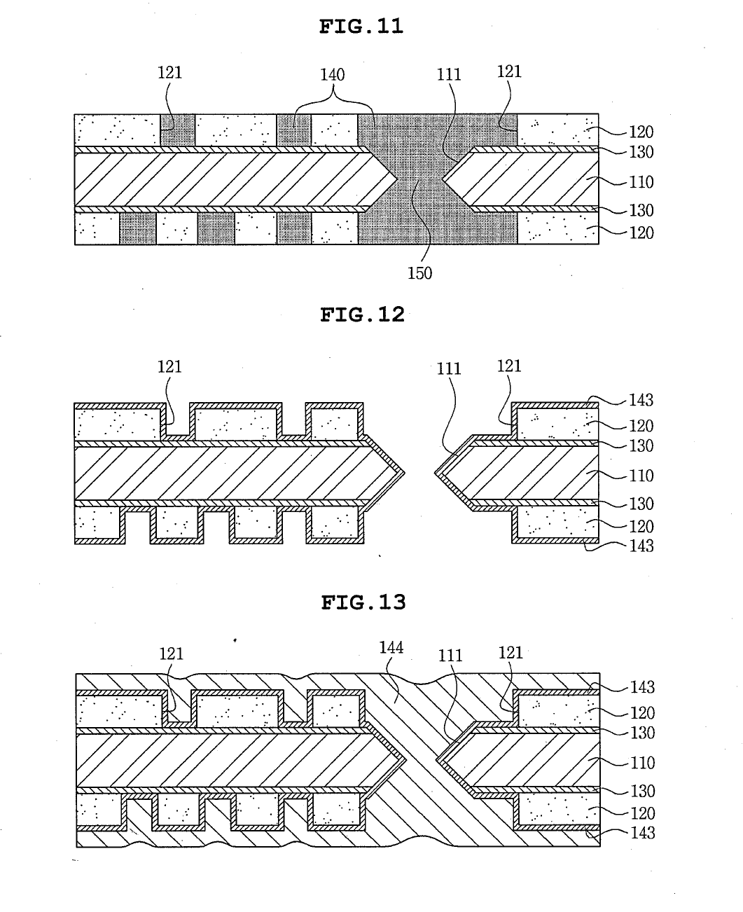

FIGS. 10 to 11 are exemplified diagrams illustrating a method of forming a circuit pattern according to another preferred embodiment of the present invention.

Referring to FIG. 10, the conductive ink 142 may be applied by an inkjet method.

According to another preferred embodiment of the present invention, the opening 121 of the positive photosensitive insulating layer 120 may be filled with the conductive ink 142 by the inkjet method. Further, the conductive ink 142 may also be filled in the through via hole 111. Since the conductive ink 142 is filled in the opening 121 of the positive photosensitive insulating layer 120, a separate buried pattern is not required. Here, the bather pattern is a pattern formed to prevent the form of the circuit pattern from changing due to flowability of the conductive ink 142.

Referring to FIG. 11, the circuit pattern 140 may be formed.

The conductive ink 142 is completely filled in the opening 121 and thus the circuit pattern 140 buried in the positive photosensitive insulating layer 120 may be formed. Further, the conductive ink 142 may be filled in the through via hole 111 to form the through via 150.

FIGS. 12 to 14 are exemplified diagrams illustrating a method of forming a circuit pattern according to another preferred embodiment of the present invention.

Referring to FIG. 12, the seed layer 143 may be formed.

The seed layer 143 may be formed on the upper surface of the positive photosensitive insulating layer 120, an inner wall of the opening 121, and an upper surface of the glass substrate 110 exposed by the opening 121. Further, the seed layer 143 may also be formed in the inner wall of the through via hole 111. The seed layer 143 may be formed by a sputtering method or the electroless plating method. The method of forming the seed layer 143 is not limited thereto, but at least one of the methods of forming a seed layer which are known in the circuit board field may be applied. The seed layer 143 may be made of a conductive metal. For example, the seed layer 143 may be made of copper. However, as a material of the seed layer 143, only the copper is not used.

Referring to FIG. 13, the plating layer 144 may be formed.

The plating layer 144 may be formed on the seed layer 143 by the electroplating. The plating layer 144 may be made of the conductive metal. For example, the plating layer 144 may be made of copper. However, as the material of the plating layer 144, only the copper is not used. As illustrated in FIG. 13, the plating layer 144 may also be formed on the opening 121 and the positive photosensitive insulating layer 120.

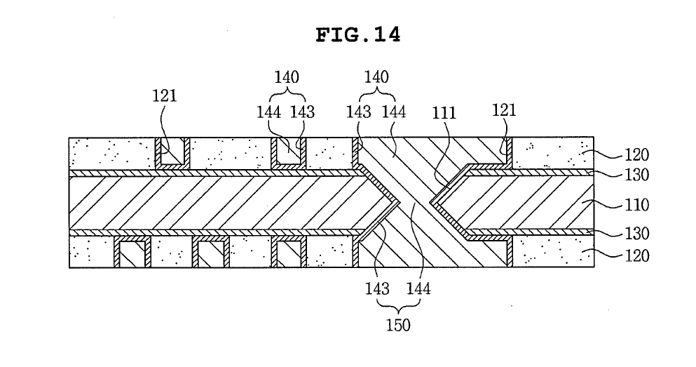

Referring to FIG. 14, the circuit pattern 140 may be formed.

When the plating layer 144 is plated up to the upper surface of the positive photosensitive insulating layer 120, the polishing may be performed. The plating layer 144 may be removed till the upper surface of the positive photosensitive insulation layer 120 is exposed by the polishing. Therefore, the circuit pattern 140 which is configured of the seed layer 143 and the plating layer 144 which are buried in the positive photosensitive insulating layer 120 may be formed. Further, the through via 150 which is configured of the seed layer 143 and the plating layer 144 formed in the through via hole 111 may be formed.

The circuit pattern 140 buried in the positive photosensitive insulating layer 120 may be formed by the polishing. Further, the flatness of the positive photosensitive insulating layer 120 and the circuit pattern 140 may be improved by the polishing.

According to the preferred embodiment of the present invention, any conductive material which is used in the circuit board field may be applied to the conductive paste 141, the conductive ink 142, the seed layer 143, and the plating layer 144 without being limited.

According to the method of manufacturing a printed circuit board according to the preferred to embodiment of the present invention, the printed circuit board having the large rigidity and the small deformation degree due to the change in temperature and humidity by using the glass substrate may be formed. That is, according to the method of manufacturing a printed circuit board, the warpage of the printed circuit board may be reduced. Further, according to the method of manufacturing a printed circuit board, the roll-to-roll process may be easily applied by using the glass substrate having flexibility. Further, the glass substrate having flexibility has low brittleness and therefore does not easily break from the external impact, and may facilitate the manufacturing of the printed circuit board having the curved surface. Further, according to the method of manufacturing a printed circuit board, the fine pattern may be formed by the smooth glass substrate and the positive photosensitive insulating layer which may be finely patterned. Further, according to the preferred embodiment of the present invention, the circuit pattern is formed by a method of filling the conductive material in the opening of the positive photosensitive insulating layer, thereby preventing an under cut from occurring in the circuit pattern.

According to the printed circuit board and the method of manufacturing a printed circuit board, the positive photosensitive insulating layer of one layer and the circuit pattern are formed, but the layer number of the printed circuit board is not limited thereto. According to the preferred embodiment of the present invention, a multi-layer build up layer may be further formed on the printed circuit board by according to a selection of a person having ordinary skill in the art to which the present invention pertains.

According to the printed circuit board and the method of manufacturing a printed circuit board according to the preferred embodiments of the present invention, the under cut may be prevented by forming the buried circuit pattern.

According to the printed circuit board and the method of manufacturing a printed circuit board according to the preferred embodiments of the present invention, the rigidity may be improved by using the glass substrate.

According to the printed circuit board and the method of manufacturing a printed circuit board according to the preferred embodiments of the present invention, the warpage may be reduced by using the glass substrate.

According to the printed circuit board and the method of manufacturing a printed circuit board according to the preferred embodiments of the present invention, the fine pattern may be easily implemented by using the positive photosensitive insulating layer.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a glass substrate through which light is not transmitted;
a positive photosensitive insulating layer formed on the glass substrate; and
a circuit pattern formed on the glass substrate and buried in the positive photosensitive insulating layer.

2. The printed circuit board as set forth in claim 1, further comprising:
a through via penetrating through the glass substrate to be connected to the circuit pattern.

3. The printed circuit board as set forth in claim 1, further comprising:
an adhesive layer formed between the glass substrate and the positive photosensitive insulating layer.

4. The printed circuit board as set forth in claim 1, wherein the glass substrate is opaque.

5. The printed circuit board as set forth in claim 1, wherein the glass substrate has flexibility.

6. The printed circuit board as set forth in claim 1, wherein the positive photosensitive insulating layer is formed on both surfaces of the glass substrate.

7. A method of manufacturing a printed circuit board, comprising:
providing a glass substrate through which light is not transmitted;
forming a positive photosensitive insulating layer on the glass substrate;
forming an opening on the positive photosensitive insulating layer; and
forming a circuit pattern by filling the opening with a conductive material.

8. The method as set forth in claim 7, wherein in the providing of the glass substrate, the glass substrate is opaque.

9. The method as set forth in claim 7, wherein the glass substrate is formed of a glass plate which has flexibility.

10. The method as set forth in claim 7, wherein the forming of the opening on the positive photosensitive insulating layer includes:
exposing a region formed with the opening in the positive photosensitive insulating layer; and
forming the opening by removing the exposed region by a develop process.

11. The method as set forth in claim 10, wherein the exposing includes:
forming a patterned mask on the positive photosensitive insulating layer to expose a region formed with the opening;
exposing a region exposed by the mask in the positive photosensitive insulating layer; and
removing the mask.

12. The method as set forth in claim 10, wherein in the exposing, the region formed with the opening in the positive photosensitive insulating layer is exposed by a laser direct imaging (LDI) method.

13. The method as set forth in claim 7, wherein in the forming of the circuit pattern, the opening is filled with a conductive paste by a screen printing method.

14. The method as set forth in claim 7, wherein in the forming of the circuit pattern, the opening is filled with conductive ink by an inkjet method.

15. The method as set forth in claim 7, wherein the forming of the circuit pattern includes:
forming a seed layer on the positive photosensitive insulating layer and the opening;
forming a plating layer on the seed layer that the opening is filled by plating; and
forming the circuit pattern by polishing the plating layer so as to expose one surface of the positive photosensitive insulating layer.

16. The method as set forth in claim 7, further comprising:
after the forming of the opening, forming a through via hole which penetrates through the glass substrate.

17. The method as set forth in claim 16, wherein in the forming of the through via hole, the through via hole is formed by a CNC drill or a laser drill.

18. The method as set forth in claim 16, wherein in the forming of the circuit pattern, a through via is formed by filling the through via hole with the conductive material.

19. The method as set forth in claim 7, further comprising:
prior to the forming of the positive photosensitive insulating layer, forming an adhesive layer on the glass substrate.

20. The method as set forth in claim 7, wherein in the forming of the positive photosensitive insulating layer, the positive photosensitive insulating layer is formed on both surfaces of the glass substrate.
